(19) United States
(12) Patent Application Publication
(10) Pub. No.: US 2025/0029883 A1
(43) Pub. Date: Jan. 23, 2025

(54) SEMICONDUCTOR MODULE AND METHOD FOR MANUFACTURING SEMICONDUCTOR MODULE

(71) Applicant: FUJI ELECTRIC CO., LTD., Kanagawa (JP)

(72) Inventor: Shohei KASAI, Matsumoto-city (JP)

(21) Appl. No.: 18/673,318

(22) Filed: May 24, 2024

(30) Foreign Application Priority Data
Jul. 18, 2023 (JP) 2023-117058

(51) Int. Cl. H01L 23/31; H01L 23/00; H01L 23/29; H01L 23/498

(52) U.S. Cl. CPC H01L 23/3135; H01L 23/296; H01L 23/3121; H01L 23/49822; H01L 24/48; H01L 2224/48091; H01L 2224/48245; H01L 2924/351

(57) ABSTRACT

Providing a semiconductor module, including: a laminated substrate; multiple semiconductor chips provided on the laminated substrate; a bonding wire connected to the multiple semiconductor chips; a housing which accommodates the multiple semiconductor chips, the bonding wire, and the laminated substrate; a first encapsulation layer which covers the multiple semiconductor chips, the bonding wire, and the laminated substrate inside the housing; a second encapsulation layer provided on the first encapsulation layer; and a third encapsulation layer provided on the second encapsulation layer. The first encapsulation layer is filled inside the housing up to a position higher than an upper surface of the bonding wire, and hardness of the second encapsulation layer is greater than hardness of the first encapsulation layer and less than hardness of the third encapsulation layer.

The contents of the following patent application(s) are incorporated herein by reference:
NO. 2023-117058 filed in JP on Jul. 18, 2023

### BACKGROUND

### 1. Technical Field

The present invention relates to a semiconductor module and a method for manufacturing the semiconductor module.

### 2. Related Art

Patent document 1 describes about a semiconductor module provided with “a second sealing material 8 containing a resin composition according to a first embodiment so as to cover a first sealing material 7”. Patent document 2 describes about a semiconductor module having structure in which “a protective layer 21 is provided in contact with a sealing layer 20”. Patent document 3 describes about a semiconductor module including a second resin 44 that is relatively softer than a first resin 42, and a third resin 46 that is relatively harder than the second resin 44.

### PRIOR ART DOCUMENTS

### Patent Documents

Patent Document 1: Japanese Patent Application Publication No. 2017-171714
Patent Document 2: Japanese Patent Application Publication No. 2022-148684
Patent Document 3: Japanese Patent Application Publication No. 2022-64191

### BRIEF DESCRIPTION OF THE DRAWINGS

FIG. 1A illustrates an example of a top view of a semiconductor chip 100 according to example 1.

FIG. 1B illustrates an example of a top view of the semiconductor chip 100.

FIG. 1C illustrates an example of a cross-section a-a′ taken in FIG. 1B.

FIG. 2 illustrates an example of structure of a semiconductor module 200.

FIG. 3A illustrates an example of a method for manufacturing the semiconductor module 200.

FIG. 3B illustrates an example of filling an encapsulation resin 220.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are imperative to the solving means of the invention.

In the present specification, one side in a thickness direction of a semiconductor chip 100 is referred to as “upper”, and another side is referred to as “lower”. Out of two principal surfaces of a device, a substrate, a layer, a film, or another member, one principal surface is referred to as an upper surface, and another principal surface is referred to as a lower surface. The “upper” and “lower” directions are not limited to the gravitational direction. In the present example, the up-down direction is referred to as a Z axis direction, and two directions orthogonal to each other in a plane perpendicular to the Z axis direction are respectively referred to as an X axis direction and a Y axis direction. The XYZ axes constitute the right-handed system. A top view refers to seeing the semiconductor chip 100 from a +Z axis direction.

Each embodiment shows an example in which a first conductivity type is set as an N type, and a second conductivity type is set as a P type; however, the first conductivity type may be the P type, and the second conductivity type may be the N type. In this case, conductivity types of the substrate, the layer, a region, and the like in each embodiment will have opposite polarities. Each of the layers and regions noted with N or P means that electrons or holes are majority carriers. In addition, when the signs + and − are affixed to N and P, it means that the layers or regions have higher/lower doping concentrations than the layers or regions without the signs + and −.

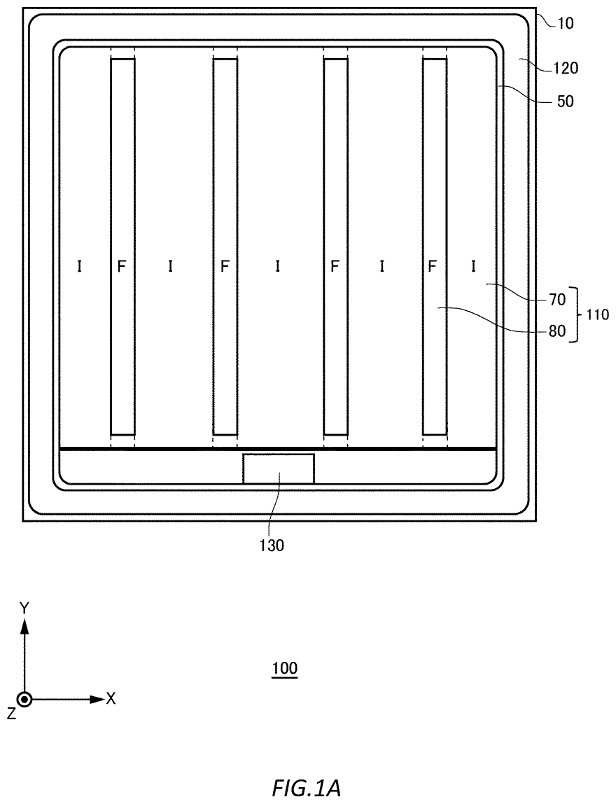

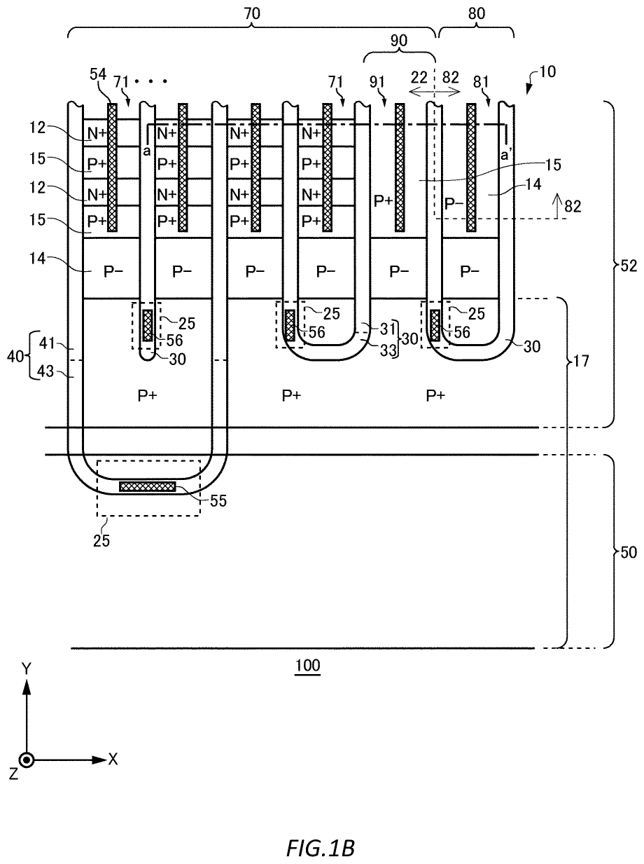

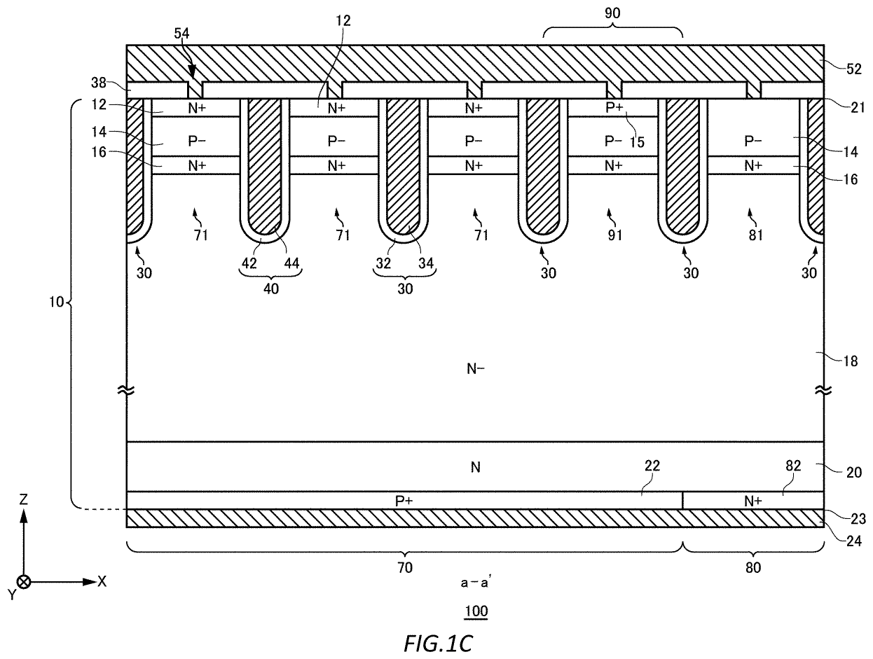

FIG. 1A illustrates an example of a top view of a semiconductor chip 100 according to example 1. The semiconductor chip 100 is a semiconductor chip that includes a transistor portion 70 and a diode portion 80.

The transistor portion 70 includes a transistor such as an insulated gate bipolar transistor (IGBT). The diode portion 80 includes a diode such as a free wheel diode (FWD). The semiconductor chip 100 of the present example is a reverse conducting IGBT (RC-IGBT) having the transistor portion 70 and the diode portion 80 on one chip.

The semiconductor substrate 10 may be a silicon substrate, may be a silicon carbide substrate, or may be a nitride semiconductor substrate such as gallium nitride, or the like. The semiconductor substrate 10 in the present example is the silicon substrate. The semiconductor substrate 10 has an active region 110 and an outer peripheral region 120.

The transistor portion 70 is a region obtained by projecting a collector region provided on a lower surface side of the semiconductor substrate 10 onto an upper surface of the semiconductor substrate 10. The collector region is of the second conductivity type. By way of example, the collector region is of the P+ type.

The diode portion 80 is a region obtained by projecting a cathode region provided on the lower surface side of the semiconductor substrate 10 onto the upper surface of the semiconductor substrate 10. The cathode region is of the first conductivity type. By way of example, the cathode region of the present example is of the N+ type.

The transistor portion 70 and the diode portion 80 may be arrayed alternately in a cyclical manner on the XY plane. The transistor portion 70 and the diode portion 80 of the present example have multiple transistor portions and diode portions. In a region between the transistor portion 70 and the diode portion 80, a gate metal layer 50 may be provided on the semiconductor substrate 10.

Note that, the transistor portion 70 and the diode portion 80 of the present example have trench portions extending in the Y axis direction. However, the transistor portion 70 and the diode portion 80 may have trench portions that extend in the X axis direction.

The active region 110 has the transistor portion 70 and the diode portion 80. The active region 110 is a region in which a main current flows between the upper surface and a lower surface of the semiconductor substrate 10 when the semiconductor chip 100 is controlled to an ON state. In other words, the active region is a region in which current flows inside the semiconductor substrate 10 in the depth direction from the upper surface to the lower surface or from the lower surface to the upper surface of the semiconductor substrate 10. In the present specification, the transistor portions 70 and the diode portions 80 may be referred to as device portions or device regions.

Note that, in a top view, a region sandwiched by two device portions is referred to as an active region 110. In the present example, a region that is sandwiched between the device portions and where the gate metal layer 50 is provided is also included in the active region 110.

The gate metal layer 50 is formed of a material including metal. For example, the gate metal layer 50 is formed of aluminum, aluminum-silicon alloy, or aluminum-silicon-copper alloy. The gate metal layer 50 is electrically connected to a gate conductive portion of the transistor portion 70 and supplies a gate voltage to the transistor portion 70. The gate metal layer 50 is provided such that the outer periphery of the active region 110 will be surrounded in the top view. The gate metal layer 50 is electrically connected to the gate pad 130 provided in the outer peripheral region 120. The gate metal layer 50 may be provided along the outer peripheral end of the semiconductor substrate 10. Further, the gate metal layer 50 may be provided between the transistor portion 70 and the diode portion 80 in the top view.

In the top view, the outer peripheral region 120 is a region between the active region 110 and the outer peripheral end of the semiconductor substrate 10. The outer peripheral region 120 is, in a top view, provided around the active region 110. In the outer peripheral region 120, one or more metal pad for connecting the semiconductor chip 100 and an external device by means of a wire etc. may be arranged. Note that, the outer peripheral region 120 may have an edge termination structure portion. The edge termination structure portion reduces electric field strength on the upper surface side of the semiconductor substrate 10. For example, the edge termination structure portion has a structure of a guard ring, a field plate, an RESURF, and a combination thereof.

The gate pad 130 is electrically connected to the gate conductive portion of the transistor portion 70 via the gate metal layer 50. The gate pad 130 is set to a gate potential. The gate pad 130 in the present example has a rectangular shape in the top view.

FIG. 1B illustrates an example of a top view of the semiconductor chip 100. In the present example, there is shown an enlarged view of the end portion of the active region 110.

The transistor portion 70 is a region obtained by projecting a collector region 22 provided on a back surface side of a semiconductor substrate 10 onto an upper surface of the semiconductor substrate 10. The collector region 22 is of the second conductivity type. By way of example, the collector region 22 in the present example is of the P+ type. The transistor portion 70 includes a boundary portion 90 that is positioned in a boundary between the transistor portion 70 and the diode portion 80.

The diode portion 80 is a region obtained by projecting a cathode region 82 provided on the back surface side of the semiconductor substrate 10 onto the upper surface of the semiconductor substrate 10. The cathode region 82 is of the first conductivity type. By way of example, the cathode region 82 in the present example is of the N+ type.

The semiconductor chip 100 of the present example includes, on a front surface of the semiconductor substrate 10, a gate trench portion 40, a dummy trench portion 30, an emitter region 12, a base region 14, a contact region 15, and a well region 17. Also, the semiconductor chip 100 of the present example also includes an emitter electrode 52 and a gate metal layer 50 provided on the front surface of the semiconductor substrate 10.

The emitter electrode 52 is provided above the gate trench portion 40, the dummy trench portion 30, the emitter region 12, the base region 14, the contact region 15, and the well region 17. In addition, the gate metal layer 50 is provided above the gate trench portion 40 and the well region 17. The emitter electrode 52 of the present example is set to an emitter potential of the transistor portion 70. The emitter electrode 52 is an example of a front surface electrode which is provided above the semiconductor substrate 10 and is electrically connected to the transistor portion 70 and the diode portion 80.

The emitter electrode 52 and the gate metal layer 50 are formed of a material containing metal. For example, at least a part of a region of the emitter electrode 52 may be formed of aluminum, aluminum-silicon alloy, or aluminum-silicon-copper alloy. The emitter electrode 52 may have barrier metal formed of titanium, titanium compound, and the like under the region formed of aluminum and the like. The emitter electrode 52 and the gate metal layer 50 are provided separately from each other.

The emitter electrode 52 and the gate metal layer 50 are provided above the semiconductor substrate 10 to sandwich an interlayer dielectric film 38. The interlayer dielectric film 38 is omitted in FIG. 1B. A contact hole 54, a contact hole 55, and a contact hole 56 are provided to penetrate through the interlayer dielectric film 38.

The contact holes 55 connect the gate metal layer 50 and the gate conductive portions inside the transistor portions 70. Inside the contact hole 55, a plug formed of tungsten or the like may be formed.

The contact hole 56 connects the emitter electrode 52 with a dummy conductive portion inside the dummy trench portion 30. Inside the contact hole 56, a plug formed of tungsten or the like may be formed.

A connection portion 25 electrically connects the emitter electrode 52, the gate metal layer 50, or the like to the semiconductor substrate 10. In an example, the connection portion 25 is provided between the gate metal layer 50 and the gate conductive portion. The connection portion 25 is also provided between the emitter electrode 52 and the dummy conductive portion. The connection portion 25 is formed of a conductive material such as polysilicon doped with an impurity. Herein, the connection portion 25 is formed of polysilicon (N+) doped with the impurities of the N type. The connection portion 25 is provided above the front surface of the semiconductor substrate 10 via an insulating film such as an oxide film or the like.

The gate trench portions 40 are arrayed at a predetermined interval along a predetermined array direction (in the present example, the X axis direction). The gate trench portion 40 in the present example may have two extending portions 41 extending along the extending direction (in the present example, the Y axis direction) that is parallel to the front surface of the semiconductor substrate 10 and perpendicular to the array direction and a connection part 43 connecting the two extending portions 41.

At least a part of the connection part 43 is preferably formed in a curved shape. By connecting end portions of the two extending portions 41 of the gate trench portion 40, electric field strength at the end portions of the extending portions 41 can be reduced. The gate metal layer 50 may be connected to the gate conductive portion at the connection part 43 of the gate trench portion 40.

The dummy trench portion 30 is a trench portion electrically connected to the emitter electrode 52. Similar to the gate trench portions 40, the dummy trench portions 30 are arrayed at a predetermined interval along a predetermined array direction (in the present example, the X axis direction). The dummy trench portion 30 of the present example may have, similar to the gate trench portion 40, a U shape at the front surface of the semiconductor substrate 10. That is, the dummy trench portion 30 may have two extending portions 31 which extend along the extending direction and a connection part 33 which connects the two extending portions 31.

The transistor portion 70 of the present example has a structure in which the two gate trench portions 40 and three dummy trench portions 30 are arrayed repeatedly. That is, the transistor portion 70 of the present example has the gate trench portions 40 and the dummy trench portions 30 at a ratio of 2:3. For example, the transistor portion 70 has one extending portion 31 between two extending portions 41. In addition, the transistor portion 70 has two extending portions 31 adjacent to the gate trench portion 40.

It is noted however that the ratio of the gate trench portions 40 and the dummy trench portions 30 is not limited to the present example. The ratio of the gate trench portions 40 and the dummy trench portions 30 may be 1:1 or may be 2:4. In addition, the transistor portion 70 may be entirely provided with the gate trench portion 40 without being provided with the dummy trench portion 30.

The well region 17 is the region, of the second conductivity type, provided on the front surface side of the semiconductor substrate 10 relative to the drift region 18, which will be described below. The well region 17 is an example of a well region provided on an edge side of the semiconductor chip 100. By way of example, the well region 17 is of the P+ type. The well region 17 is formed within a predetermined range from an end portion of the active region on a side in which the gate metal layer 50 is provided. A diffusion depth of the well region 17 may be deeper than depths of the gate trench portion 40 and the dummy trench portion 30. Some regions of the gate trench portion 40 and the dummy trench portion 30 on the side of the gate metal layer 50 are formed in the well region 17. The bottoms at the end of the extending direction of the gate trench portion 40 and the dummy trench portion 30 may be covered by the well region 17.

The contact hole 54 is formed above each region of the emitter region 12 and the contact region 15 in the transistor portion 70. Also, the contact hole 54 is provided above the base region 14 in the diode portion 80. The contact hole 54 is provided above the contact region 15 in the boundary portion 90. The contact hole 54 is provided above the base region 14 in the diode portion 80. No contact holes 54 are provided above the well regions 17 provided at both ends in the Y axis direction. In this manner, one or more contact holes 54 are formed in the interlayer dielectric film. The one or more contact holes 54 may be provided to extend in the extending direction.

The boundary portion 90 is a region provided in the transistor portion 70, and is adjacent to the diode portion 80. The boundary portion 90 has the contact region 15. The boundary portion 90 in the present example does not have the emitter region 12. In an example, the trench portions in the boundary portion 90 are the dummy trench portions 30. The boundary portion 90 in the present example has the dummy trench portions 30 such that they are arranged at the both ends in the X axis direction.

The mesa portion 71, the mesa portion 91 and the mesa portion 81 are mesa portions provided in direct contact with the trench portions, in a plane parallel to the front surface of the semiconductor substrate 10. The mesa portion is a portion of the semiconductor substrate 10 interposed between two trench portions adjacent to each other, and may be a part ranging from the front surface of the semiconductor substrate 10 to a depth of a deepest bottom portion of each trench portion. An extending portion of each trench portion may be defined as one trench portion. That is, the region sandwiched between two extending portions may be defined as a mesa portion.

The mesa portion 71 is provided in direct contact with at least one of the dummy trench portion 30 or the gate trench portion 40 in the transistor portion 70. The mesa portion 71 has the well region 17, the emitter region 12, the base region 14, and the contact region 15, at the front surface of the semiconductor substrate 10. In the mesa portion 71, the emitter regions 12 and the contact regions 15 are alternately provided in the extending direction.

The mesa portion 91 is provided in the boundary portion 90. The mesa portion 91 has the contact region 15 and the well region 17 on the front surface of the semiconductor substrate 10.

The mesa portion 81 is provided in a region sandwiched between the dummy trench portions 30 adjacent to each other in the diode portion 80. The mesa portion 81 has, on the front surface of the semiconductor substrate 10, a base region 14, a contact region 15, and a well region 17.

The base region 14 is a region of second conductivity type provided in the transistor portion 70 and the diode portion 80 on the side of the front surface of the semiconductor substrate 10. By way of example, the base region 14 is of the P− type. The base region 14 may be provided at the both ends of the mesa portion 71 and the mesa portion 91 in the Y axis direction, on the front surface of the semiconductor substrate 10. Note that FIG. 1B shows only one end of the base region 14 in the Y axis direction.

The emitter region 12 is a region of the first conductivity type having a higher doping concentration than that of the drift region 18. By way of example, the emitter region 12 in the present example is of the N+ type. An example of a dopant of the emitter region 12 include arsenic (As). The emitter region 12 is provided in contact with the gate trench portion 40 at a front surface of the mesa portion 71. The emitter region 12 may be provided to extend in the X axis direction from one to another of two trench portions sandwiching the mesa portion 71. The emitter region 12 is also provided below the contact hole 54.

In addition, the emitter region 12 may or may not be in contact with the dummy trench portion 30. The emitter region 12 in the present example is in contact with the dummy trench portion 30. The emitter region 12 may not be provided in the mesa portion 91 of the boundary portion 90.

The contact region 15 is a region of the second conductivity type having a higher doping concentration than that of the base region 14. By way of example, the contact region 15 in the present example is of the P+ type. The contact region 15 of the present example is provided on the front surfaces of the mesa portion 71 and the mesa portion 91. The contact region 15 may be provided from one trench portion to another trench portion of two trench portions which interpose the mesa portion 71 or the mesa portion 91 therebetween in the X axis direction. The contact region 15 may be or may not be in contact with the gate trench portion 40. In addition, the contact region 15 may be, or may not be in contact with the dummy trench portion 30. In the present example, the contact region 15 is in contact with the dummy trench portion 30 and the gate trench portion 40. The contact region 15 is also provided below the contact hole 54. Note that the contact region 15 may also be provided in the mesa portion 81.

FIG. 1C illustrates an example of a cross-section a-a′ taken in FIG. 1B. The cross-section a-a′ is an XZ plane passing through the emitter region 12 in the transistor portion 70. The semiconductor chip 100 in the present example has the semiconductor substrate 10, the interlayer dielectric film 38, the emitter electrode 52, and the collector electrode 24 in the cross-section a-a′. The emitter electrode 52 is formed above the semiconductor substrate 10 and the interlayer dielectric film 38.

The drift region 18 is a region of the first conductivity type which is provided in the semiconductor substrate 10. By way of example, the drift region 18 in the present example is of the N− type. The drift region 18 may be a region which has remained without another doping region formed in the semiconductor substrate 10. That is, a doping concentration in the drift region 18 may be a doping concentration in the semiconductor substrate 10.

The buffer region 20 is a region of the first conductivity type, that is provided below the drift region 18. By way of example, the buffer region 20 in the present example is of the N type. A doping concentration in the buffer region 20 is higher than a doping concentration in the drift region 18. The buffer region 20 may function as a field stop layer which prevents a depletion layer expanding from a lower surface side of the base region 14 from reaching the collector region 22 of the second conductivity type and the cathode region 82 of the first conductivity type.

The collector region 22 is provided below the buffer region 20 in the transistor portion 70. The cathode region 82 is provided below the buffer region 20 in the diode portion 80. The boundary between the collector region 22 and the cathode region 82 is a boundary between the transistor portion 70 and the diode portion 80.

The collector electrode 24 is formed at the back surface 23 of the semiconductor substrate 10. The collector electrode 24 is formed of a conductive material such as metal.

The base region 14 is a region of the second conductivity type provided above the drift region 18, in the mesa portion 71, the mesa portion 91, and the mesa portion 81. The base region 14 is provided in contact with the gate trench portion 40. The base region 14 may be provided in contact with the dummy trench portion 30.

The emitter region 12 is, in the mesa portion 71, provided between the base region 14 and the front surface 21. The emitter region 12 is provided in contact with the gate trench portion 40. The emitter region 12 may be or may not be in contact with the dummy trench portion 30. Note that, the emitter region 12 may not need to be provided in the mesa portion 91.

The contact region 15 is provided above the base region 14 in the mesa portion 91. The contact region 15 is provided in contact with the dummy trench portions 30 in the mesa portion 91. In another cross-section, the contact region 15 may be provided at the front surface 21 of the mesa portion 71.

An accumulation region 16 is a region of the first conductivity type which is provided on the front surface 21 side of the semiconductor substrate 10 relative to the drift region 18. By way of example, the accumulation region 16 in the present example is of the N+ type. The accumulation region 16 is provided in the transistor portion 70 and the diode portion 80. The accumulation region 16 of the present example is also provided in the boundary portion 90. In this manner, in the semiconductor chip 100, a mask misalignment can be avoided in the accumulation region 16.

In addition, the accumulation region 16 is provided in contact with the gate trench portion 40. The accumulation region 16 may be or may not be in contact with the dummy trench portion 30. A doping concentration in the accumulation region 16 is higher than the doping concentration in the drift region 18. Providing the accumulation region 16 can enhance the carrier injection enhancement effect (IE effect) to reduce an ON voltage of the transistor portion 70.

One or more gate trench portions 40 and one or more dummy trench portions 30 are provided at the front surface 21. Each trench portion is provided from the front surface 21 to the drift region 18. In a region where at least any of the emitter region 12, the base region 14, the contact region 15, or the accumulation region 16 is provided, each trench portion also penetrates through these regions to reach the drift region 18. This phrase “the trench portion penetrating through the doping regions” is not limited to the one manufactured in the order of forming the doping region and then forming the trench portion. This phrase “the trench portion penetrating through the doping regions” also includes the one manufactured in the order of forming the trench portions and then forming the doping region between the trench portions.

The gate trench portion 40 has a gate trench, a gate insulating film 42, and a gate conductive portion 44 which are formed at the front surface 21. The gate insulating film 42 is formed to cover an inner wall of the gate trench. The gate insulating film 42 may be formed by oxidizing or nitriding a semiconductor on the inner wall of the gate trench. The gate conductive portion 44 is formed farther inward than the gate insulating film 42 inside the gate trench. The gate insulating film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21.

The gate conductive portion 44 includes a region opposing the adjacent base region 14 on the side of the mesa portion 71 by sandwiching the gate insulating film 42 in a depth direction of the semiconductor substrate 10. When a predetermined voltage is applied to the gate conductive portion 44, a channel is formed by an electron inversion layer in a surface layer of the base region 14 at an interface in contact with the gate trench.

The dummy trench portion 30 may have the same structure as that of the gate trench portion 40. The dummy trench portion 30 has a dummy trench, a dummy insulating film 32, and a dummy conductive portion 34 which are formed on the front surface 21 side. The dummy insulating film 32 is formed covering the inner walls of the dummy trench. The dummy conductive portion 34 is formed inside the dummy trench, and is formed farther inward than the dummy insulating film 32. The dummy insulating film 32 insulates the dummy conductive portion 34 from the semiconductor substrate 10. The dummy trench portion 30 is covered with the interlayer dielectric film 38 on the front surface 21.

The interlayer dielectric film 38 is provided on the front surface 21. The emitter electrode 52 is provided above the interlayer dielectric film 38. The interlayer dielectric film 38 is provided with one or more contact holes 54 for electrically connecting the emitter electrode 52 to the semiconductor substrate 10. Similarly, the contact hole 55 and the contact hole 56 may be provided to penetrate the interlayer dielectric film 38.

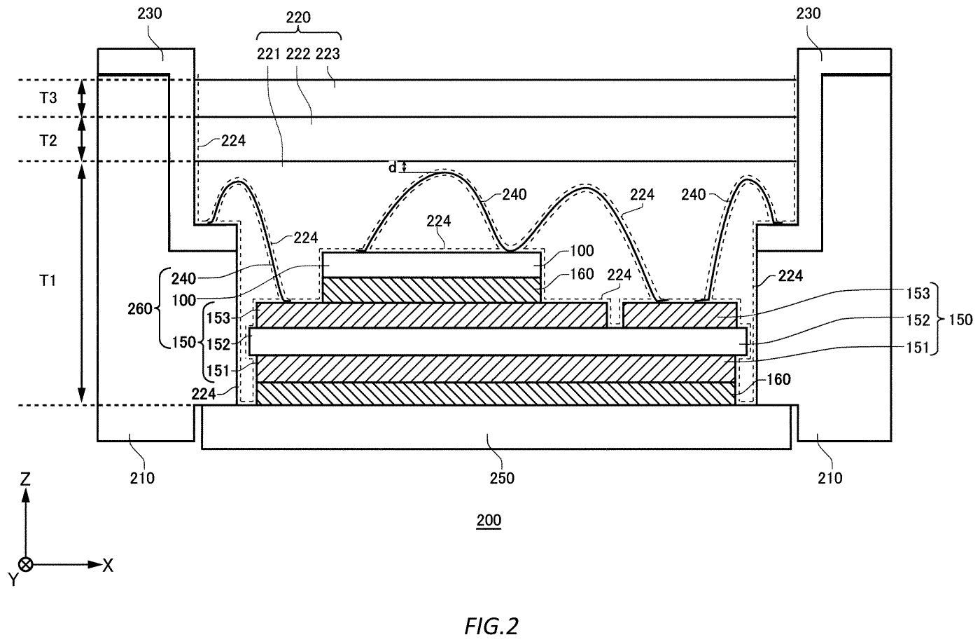

FIG. 2 illustrates an example of structure of a semiconductor module 200. The semiconductor module 200 of the present example includes the semiconductor chip 100, a laminated substrate 150, a housing 210, an encapsulation resin 220, a lead frame 230, a bonding wire 240, and a base substrate 250.

The housing 210 accommodates the semiconductor chip 100. The housing 210 of the present example has a rectangular parallelepiped shape, but the present invention is not limited to this. Side walls and a bottom portion of the housing 210 may be constituted by different members. For example, the material of the housing 210 is an insulative material such as a resin. The resin may be selected from polyphenylene sulfide (PPS), polybutylene terephthalate (PBT), polybutyl acrylate (PBA), polyamide (PA), acrylonitrile butadiene styrene (ABS), liquid crystal polymer (LCP), polyether ether ketone (PEEK), polybutylene succinate (PBS), urethane, silicon, and the like. The housing 210 of the present example accommodates a semiconductor assembly 260 composed of multiple semiconductor chips 100, the bonding wire 240, and the laminated substrate 150.

The laminated substrate 150 is provided on an upper surface of the base substrate 250. Multiple semiconductor chips 100 may be provided on the laminated substrate 150. The laminated substrate 150 includes a first metal layer 151, an insulating plate 152, and a second metal layer 153. For example, the laminated substrate 150 may be a Direct Copper Bonding (DCB) substrate or an Active Metal Brazing (AMB) substrate.

The insulating plate 152 is formed of insulative material such as ceramics including alumina (Al₂O₃), aluminum nitride (AlN), silicon nitride (Si₃N₄), and the like. The first metal layer 151 may be provided on a lower surface of the insulating plate 152, and fixed on an upper surface of the base substrate via a solder 160.

The second metal layer 153 is a conductive member provided on an upper surface of the insulating plate 152. The second metal layer 153 may include a metal wire, a pad, or the like. The first metal layer 151 and the second metal layer 153 may be formed of plates containing metal material such as copper and copper alloy. Material for the second metal layer 153 may be the same as, or different from material for the first metal layer 151. The first metal layer 151 and the second metal layer 153 may be fixed on the surfaces of the insulating plate 152 by means of solder, wax, etc. The second metal layer 153 is electrically connected to the semiconductor chip 100 by a solder 160. The second metal layer 153 is electrically connected to the lead frame 230 by means of the bonding wire 240.

The base substrate 250 is provided below the laminated substrate 150. A cooling device such as a heat sink which is not illustrated in the diagram may be provided below the base substrate 250. The base substrate 250 may be coated with thermal conductive material such as thermal interface material (TIM).

The solder 160 fixes the semiconductor chip 100 on the second metal layer 153. The solder 160 electrically and mechanically connects the semiconductor chip 100 to the second metal layer 153. The solder 160 connects the pad included in the second metal layer 153 to the collector electrode 24 of the semiconductor chip 100. For example, material for the solder 160 is Sn—Cu solder or Sn—Sb solder.

The lead frame 230 is provided being exposed to an outside of the housing 210 in order to electrically connect the semiconductor chip 100 to an external control device etc. The lead frame 230 is provided penetrating through and extending into the housing 210.

The bonding wire 240 is connected to the multiple semiconductor chips 100. The bonding wire 240 may electrically connect the multiple semiconductor chips 100 together. The bonding wire 240 may electrically connect the semiconductor chip 100 to the lead frame 230. The bonding wire 240 may electrically connect the second metal layer 153 to the lead frame 230.

The encapsulation resin 220 includes a first encapsulation layer 221 that covers the semiconductor assembly 260 composed of the multiple semiconductor chips 100, the bonding wire 240, and the laminated substrate 150 inside the housing 210. The encapsulation resin 220 includes a second encapsulation layer 222 provided on the first encapsulation layer 221. The encapsulation resin 220 includes a third encapsulation layer 223 provided on the second encapsulation layer. The encapsulation resin 220 encapsulates the semiconductor assembly 260 inside the housing 210, so that a waterproof property of the semiconductor module 200 is ensured while maintaining its insulation property. This can also prevent insulation failure to be caused by moisture, gas, or the like entering into the semiconductor module 200.

The encapsulation resin 220 of the present example has three layer structure formed of the first encapsulation layer 221, the second encapsulation layer 222, and the third encapsulation layer 223 which are made of materials different from each other. The encapsulation resin 220 may have four or more layer structure with layers made of materials different from each other. By having the three layer structure with the layers made of materials different from each other, the encapsulation resin 220 of the present example is formed such that its hardness and waterproof property improve from the bottom toward the top of the semiconductor module 200. This enables the waterproof property of the semiconductor module 200 to improve while preventing insulation failure. The encapsulation resin 220 may be formed such that a glass transition temperature and an elastic modulus improve from the bottom toward the top of the semiconductor module 200.

Each of the encapsulation layers may be provided such that the hardness and the waterproof property change gradually from the bottom toward the top of the semiconductor module 200, or such that the entire encapsulation layers have uniform characteristics. In this manner, the entire hardness and waterproof property of the encapsulation resin 220 can be finely adjusted according to required characteristics.

By having the three layer structure with layers made of materials different from each other, the encapsulation resin 220 of the present example is formed such that its coefficient of thermal expansion decreases from the bottom toward the top of the semiconductor module 200. This enables a crack of the encapsulation resin 220 to be prevented when heat is repeatedly applied to the semiconductor module 200.

The encapsulation resin 220 may or may not contain inorganic filler for its material. The encapsulation resin 220 of the present example does not include the inorganic filler for its material. The encapsulation resin 220 may not contain silica filler or the like containing SiO₂ for its material. This enables the encapsulation resin 220 to be less brittle, and occurrence of a split to be prevented on the encapsulation resin 220.

The first encapsulation layer 221 is filled inside the housing 210 up to a position higher than an upper surface of the bonding wire 240. In the present example, a distance d between an upper end of the first encapsulation layer 221 and an upper end of the bonding wire 240 is 0.5 mm or more, and 1.5 mm or less. The distance d may be a shortest distance between the upper end of the first encapsulation layer 221 and the upper end of the bonding wire 240, or a distance therebetween in a laminating direction of the encapsulation resin 220.

Filling the first encapsulation layer 221 up to the position higher than the upper surface of the bonding wire 240 enables occurrence of a bubble and a split to be prevented on an interface between the first encapsulation layer 221 and the second encapsulation layer 222, and insulation failure to be prevented for the semiconductor module 200. Also, separating the upper end of the first encapsulation layer 221 and the upper end of the bonding wire 240 by the distance d enables the bonding wire 240 to avoid contacting the second encapsulation layer 222 even when the semiconductor module 200 experiences thermal distortion, and insulation failure to be prevented for the semiconductor module 200.

A film thickness T1 of the first encapsulation layer 221 is thicker than a film thickness T2 of the second encapsulation layer 222 and a film thickness T3 of the third encapsulation layer 223. In the present specification, the film thickness of the each of the encapsulation layers may be an average value or a maximum value of a film thickness in the laminating direction of the encapsulation resin 220. The film thickness T1 of the first encapsulation layer 221 may be an average value or a maximum value of a distance from a lowest end to a highest end of the first encapsulation layer 221 in the laminating direction (the Z axis direction) of the encapsulation resin 220. The film thickness T1 of the first encapsulation layer 221 may be 50% or more, and 70% or less the entire film thickness of the encapsulation resin 220. By way of example, the entire film thickness of the encapsulation resin 220 is 6.5 mm, and the film thickness T1 of the first encapsulation layer 221 is 3.5 mm or more and 4.5 mm or less.

The first encapsulation layer 221 is made of material having a high insulation property compared to that of another encapsulation layer. In an example, the first encapsulation layer 221 contains silicone gel material or fluorogel material. Making the first encapsulation layer 221 with the material having high insulation property enables insulation failure to be avoided between conductive components in the semiconductor module 200 upon operation of the semiconductor module 200.

The second encapsulation layer 222 is provided on the upper surface of the first encapsulation layer 221. The second encapsulation layer 222 is made of material of which hardness is greater than that of the first encapsulation layer 221. In the present specification, the hardness may mean penetration hardness. Hardness of the second encapsulation layer 222 may be the penetration hardness of the second encapsulation layer 222 after the second encapsulation layer 222 is hardened through annealing.

The second encapsulation layer 222 is made of material of which a coefficient of thermal expansion is less than that of the first encapsulation layer 221. The second encapsulation layer 222 is made of material having heat-resisting property and stress reduction characteristic better than those of the first encapsulation layer 221. In an example, the second encapsulation layer 222 contains silicone elastomer material. This enables impact to be prevented from reaching the third encapsulation layer 223 even when degradation, a split, etc. is caused in the first encapsulation layer 221 due to thermal distortion.

The second encapsulation layer 222 may be made of material of which a glass transition temperature is higher than that of the first encapsulation layer 221. The second encapsulation layer 222 may be made of material of which an elastic modulus is higher than that of the first encapsulation layer 221. This enables reduction effect to be effective on a crack caused due to repeated thermal history.

The film thickness T2 of the second encapsulation layer 222 is thinner than the film thickness T1 of the first encapsulation layer 221. The film thickness T2 of the second encapsulation layer 222 may be an average value or a maximum value of a distance from a lowest end to a highest end of the second encapsulation layer 222 in the laminating direction (the Z axis direction) of the encapsulation resin 220. The film thickness T2 of the second encapsulation layer 222 may be equal to or different from the film thickness T3 of the third encapsulation layer 223.

The third encapsulation layer 223 is provided on an upper surface of the second encapsulation layer 222. The third encapsulation layer 223 is made of material of which hardness is greater than that of the second encapsulation layer 222. That is, the second encapsulation layer 222 is made of material of which the hardness is less than that of the third encapsulation layer 223. Making the hardness of the third encapsulation layer 223 be greater than the hardness of the first encapsulation layer 221 and the second encapsulation layer 222 enables impact of degradation, a split, etc. caused inside the semiconductor module 200 to be reduced, and an insulation property of the semiconductor module 200 to increase.

The third encapsulation layer 223 is made of material of which a coefficient of thermal expansion is less than that of the second encapsulation layer 222. That is, the second encapsulation layer 222 is made of material of which the coefficient of thermal expansion is larger than that of the third encapsulation layer 223.

The third encapsulation layer 223 is made of material having a high waterproof property compared to that of another encapsulation layer. In an example, the third encapsulation layer 223 contains silicone gel material. Making the third encapsulation layer 223 with material having a high waterproof property enables the waterproof property of the semiconductor module 200 to be ensured even when the semiconductor module 200 is used under a high humidity condition in a ship etc., for example.

The third encapsulation layer 223 may be made of material of which a glass transition temperature is higher than that of the second encapsulation layer 222. The third encapsulation layer 223 may be made of material of which an elastic modulus is higher than that of the second encapsulation layer 222. This enables reduction effect to be effective on a crack caused due to repeated thermal history.

The film thickness T3 of the third encapsulation layer 223 is thinner than the film thickness T1 of the first encapsulation layer 221. The film thickness T3 of the third encapsulation layer 223 may be an average value or a maximum value of a distance from a lowest end to a highest end of the third encapsulation layer 223 in the laminating direction (the Z axis direction) of the encapsulation resin 220. The film thickness T3 of the third encapsulation layer 223 may be equal to the film thickness T2 of the second encapsulation layer 222. In the present specification, a film thickness of an encapsulation layer being equal to another film thickness means a difference between these film thicknesses is 0.5% or less.

The semiconductor module 200 may include a primer layer 224 provided between the first encapsulation layer 221, and the multiple semiconductor chips 100, the bonding wire 240, and the laminated substrate 150. The primer layer 224 may be provided on an inner side wall of the housing 210. A film thickness of the primer layer 224 may be thinner than the film thickness T1 of the first encapsulation layer 221, the film thickness T2 of the second encapsulation layer 222, and the film thickness T3 of the third encapsulation layer 223. In an example, the film thickness of the primer layer 224 is 0 μm or more, and 10 μm or less.

The primer layer 224 is made of material that functions as an anti-sulfurization agent. In an example, the primer layer 224 contains polyamide, polyimide or amideimide materials. Providing the primer layer 224 enables operation stability of the semiconductor module 200 to improve.

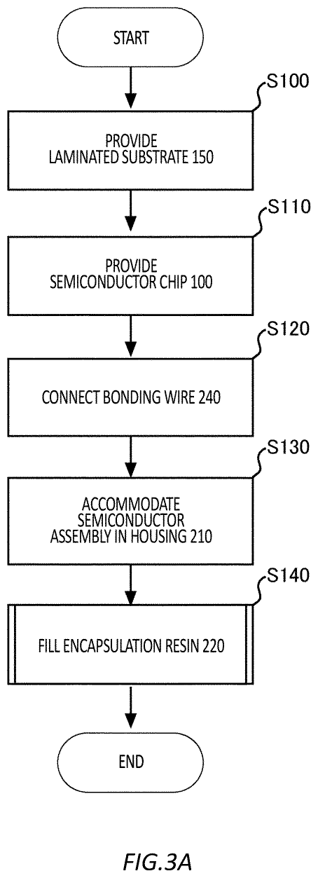

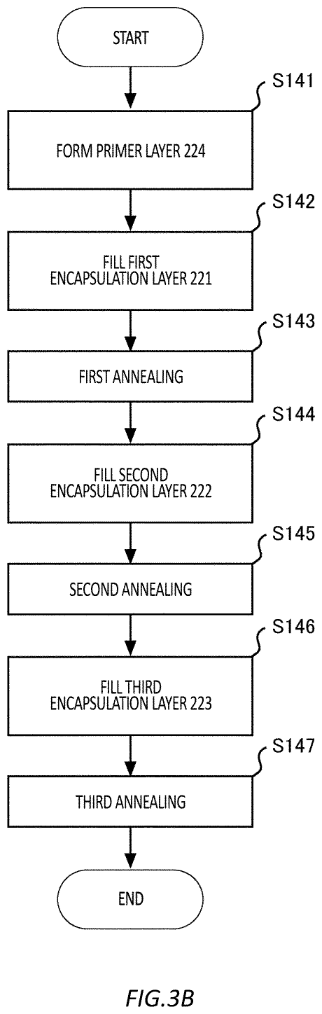

FIG. 3A is a flowchart showing an example of a method for manufacturing the semiconductor module 200. The method for manufacturing the present example include a step S100 for providing the laminated substrate 150. The method for manufacturing the present example includes a step S110 for providing the multiple semiconductor chips 100 on the laminated substrate 150. The method for manufacturing the present example includes a step S120 for connecting the multiple semiconductor chips 100 to the bonding wire 240. The method for manufacturing the present example includes a step S130 for accommodating the semiconductor assembly 260 composed of the multiple semiconductor chips 100, the bonding wire 240, and the laminated substrate 150 inside the housing 210. The method for manufacturing the present example includes a step S140 for filling the encapsulation resin 220. Each step except the step S140 for filling the encapsulation resin 220 can be performed by a usual method that can be understood by persons skilled in the art, thus there is no description for the each step in the present specification.

FIG. 3B is a flowchart showing an example of the step S140 for filling the encapsulation resin 220. The step S140 for filling the encapsulation resin 220 includes a step S141 for forming the primer layer 224, a step S142 for filling the first encapsulation layer 221, a step S143 for first annealing, a step S144 for filling the second encapsulation layer 222, a step S145 for second annealing, a step S146 for filling the third encapsulation layer 223, and a step S147 for third annealing.

In the step S141 for forming the primer layer 224, the primer layer 224 is laminated on a surface of the semiconductor assembly 260 accommodated inside the housing 210. The lamination of the primer layer 224 may be performed by chemical vapor deposition (CVD) or the like. This enables the primer layer 224 to be formed uniformly. The step S141 for forming the primer layer 224 can be omitted.

In the step S142 for filling the first encapsulation layer 221, resin for forming the first encapsulation layer 221 is filled into the housing 210. In the step S142 for filling the first encapsulation layer 221, the resin is filled inside the housing 210 such that the first encapsulation layer 221 covers the multiple semiconductor chips 100, the bonding wire 240, and the laminated substrate 150.

That is, the first encapsulation layer 221 is filled inside the housing 210 up to the position higher than the upper surface of the bonding wire 240.

In the step S143 for first annealing, the first encapsulation layer 221 is hardened. The step S143 for first annealing is performed after the step S142 for filling the first encapsulation layer 221, and prior to the step S144 for filling the second encapsulation layer 222. In the step S143 for first annealing, the first encapsulation layer 221 may not be completely hardened. A condition to meet the step S143 for first annealing can be achieved with a temperature lower than that of a condition for completely hardening the first encapsulation layer 221, or with a heating time shorter than that of a condition for completely hardening the first encapsulation layer 221. Shortening time for the step S143 for first annealing enables required time for forming the encapsulation resin 220 to be shortened. The temperature used in the step S143 for first annealing is 50 degrees Celsius or more, and 65 degrees Celsius or less, by way of example.

In the step S144 for filling the second encapsulation layer 222, resin for forming the second encapsulation layer 222 is filled into the housing 210. Because the first encapsulation layer 221 is hardened or semi-hardened in the step S143 for first annealing, the second encapsulation layer 222 can be formed such that a top of the first encapsulation layer 221 will be covered.

In the step S145 for second annealing, the second encapsulation layer 222 is hardened. The step S145 for second annealing is performed after the step S144 for filling the second encapsulation layer 222, and prior to the step S146 for filling the third encapsulation layer 223. In the step S145 for second annealing, the first encapsulation layer 221 and the second encapsulation layer 222 may not be completely hardened. A condition to meet the step S145 for second annealing can be achieved with a temperature lower than those of conditions for completely hardening the first encapsulation layer 221 and the second encapsulation layer 222, or with a heating time shorter than those of conditions for completely hardening the first encapsulation layer 221 and the second encapsulation layer 222. Shortening time for the step S145 for second annealing enables required time for forming the encapsulation resin 220 to be shortened. The temperature used in the step S145 for second annealing is 50 degrees Celsius or more, and 65 degrees Celsius or less, by way of example.

In the step S146 for filling the third encapsulation layer 223, resin for forming the third encapsulation layer 223 is filled into the housing 210. Because the second encapsulation layer 222 is hardened or semi-hardened in the step S143 for first annealing and the step S145 for second annealing, the third encapsulation layer 223 can be formed such that a top of the second encapsulation layer 222 will be covered. The third encapsulation layer 223 may be filled on the second encapsulation layer 222 up to a height equal to an upper surface of the housing 210.

In the step S147 for third annealing, the third encapsulation layer 223 is hardened. The step S147 for third annealing is performed after the step S146 for filling the third encapsulation layer 223. In the step S147 for third annealing, the first encapsulation layer 221, the second encapsulation layer 222, and the third encapsulation layer 223 may not completely hardened. A condition to meet the step S147 for third annealing can be achieved with a temperature lower than those of conditions for completely hardening the first encapsulation layer 221, the second encapsulation layer 222, and the third encapsulation layer 223, or with a heating time shorter than those of conditions for completely hardening the first encapsulation layer 221, the second encapsulation layer 222, and the third encapsulation layer 223. Shortening time for the step S147 for third annealing enables required time for forming the encapsulation resin 220 to be shortened. The temperature used in the step S147 for third annealing is 50 degrees Celsius or more, and 65 degrees Celsius or less, by way of example.

After the step S147 for third annealing, additional step for annealing may be included for hardening the first encapsulation layer 221, the second encapsulation layer 222, and the third encapsulation layer 223. A temperature used in the additional step for annealing is 185 degrees Celsius, by way of example.

While the present invention has been described by way of the embodiments, the technical scope of the present invention is not limited to the above described embodiments. It is apparent to persons skilled in the art that various alterations or improvements can be made to the above described embodiments. It is also apparent from description of the claims that the embodiments to which such alterations or improvements are made can be included in the technical scope of the present invention.

It should be noted that the operations, procedures, steps, stages, and the like of each process performed by a device, system, program, and method shown in the claims, specification, or diagrams can be performed in any order as long as the order is not indicated by “prior to”, “before”, or the like and as long as the output from a previous process is not used in a later process. Even if the operation flow is described using phrases such as “first” or “then” for the sake of convenience in the claims, specification, or diagrams, it does not necessarily mean that the process must be performed in this order.

### EXPLANATION OF REFERENCES

10: semiconductor substrate;
12: emitter region;
14: base region;
15: contact region;
16: accumulation region;
17: well region;
18: drift region;
20: buffer region;
21: front surface;
22: collector region;
23: back surface;
24: collector electrode;
25: connection portion;
30: dummy trench portion;
31: extending portion;
32: dummy insulating film;
33: connection part;
34: dummy conductive portion;
38: interlayer dielectric film;
40: gate trench portion;
41: extending portion;
42: gate insulating film;
43: connection part;
44: gate conductive portion;
50: gate metal layer;
52: emitter electrode;
54: contact hole;
55: contact hole;
56: contact hole;
70: transistor portion;
71: mesa portion;
80: diode portion;
81: mesa portion;
82: cathode region;
90: boundary portion;
91: mesa portion;
100: semiconductor chip;
110: active region;
120: outer peripheral region;
130: gate pad;
150: laminated substrate;
151: first metal layer;
152: insulating plate;
153: second metal layer;
160: solder;
200: semiconductor module;
210: housing;
220: encapsulation resin;
221: first encapsulation layer;
222: second encapsulation layer;
223: third encapsulation layer;
224: primer layer;
230: lead frame;
240: bonding wire;
250: base substrate;
260: semiconductor assembly.

What is claimed is:

1. A semiconductor module, comprising:
a laminated substrate;
multiple semiconductor chips provided on the laminated substrate;
a bonding wire connected to the multiple semiconductor chips;
a housing which accommodates the multiple semiconductor chips, the bonding wire, and the laminated substrate;
a first encapsulation layer which covers the multiple semiconductor chips, the bonding wire, and the laminated substrate inside the housing;
a second encapsulation layer provided on the first encapsulation layer; and
a third encapsulation layer provided on the second encapsulation layer, wherein
the first encapsulation layer is filled inside the housing up to a position higher than an upper surface of the bonding wire, and
hardness of the second encapsulation layer is greater than hardness of the first encapsulation layer and less than hardness of the third encapsulation layer.

2. The semiconductor module according to claim 1, wherein a distance between an upper end of the first encapsulation layer and an upper end of the bonding wire is 0.5 mm or more and 1.5 mm or less.

3. The semiconductor module according to claim 1, wherein a film thickness of the first encapsulation layer is 3.5 mm or more and 4.5 mm or less.

4. The semiconductor module according to claim 1, wherein the first encapsulation layer contains silicone gel material or fluorogel material.

5. The semiconductor module according to claim 1, wherein the second encapsulation layer contains silicone elastomer material.

6. The semiconductor module according to claim 1, wherein thickness of the second encapsulation layer is thinner than thickness of the first encapsulation layer.

7. The semiconductor module according to claim 1, wherein the third encapsulation layer contains silicone gel material.

8. The semiconductor module according to claim 1, wherein thickness of the third encapsulation layer is thinner than thickness of the first encapsulation layer.

9. The semiconductor module according to claim 1, wherein thickness of the third encapsulation layer is equal to thickness of the second encapsulation layer.

10. The semiconductor module according to claim 1, wherein a coefficient of thermal expansion of the second encapsulation layer is less than a coefficient of thermal expansion of the first encapsulation layer, and greater than a coefficient of thermal expansion of the third encapsulation layer.

11. The semiconductor module according to claim 1, comprising a primer layer provided between the first encapsulation layer, and the multiple semiconductor chips, the bonding wire and the laminated substrate.

12. The semiconductor module according to claim 2, comprising a primer layer provided between the first encapsulation layer, and the multiple semiconductor chips, the bonding wire and the laminated substrate.

13. The semiconductor module according to claim 3, comprising a primer layer provided between the first encapsulation layer, and the multiple semiconductor chips, the bonding wire and the laminated substrate.

14. The semiconductor module according to claim 4, comprising a primer layer provided between the first encapsulation layer, and the multiple semiconductor chips, the bonding wire and the laminated substrate.

15. The semiconductor module according to claim 5, comprising a primer layer provided between the first encapsulation layer, and the multiple semiconductor chips, the bonding wire and the laminated substrate.

16. The semiconductor module according to claim 6, comprising a primer layer provided between the first encapsulation layer, and the multiple semiconductor chips, the bonding wire and the laminated substrate.

17. The semiconductor module according to claim 7, comprising a primer layer provided between the first encapsulation layer, and the multiple semiconductor chips, the bonding wire and the laminated substrate.

18. The semiconductor module according to claim 8, comprising a primer layer provided between the first encapsulation layer, and the multiple semiconductor chips, the bonding wire and the laminated substrate.

19. A method for manufacturing a semiconductor module, comprising:
providing a laminated substrate;
providing multiple semiconductor chips on the laminated substrate;
connecting the multiple semiconductor chips to a bonding wire;
accommodating the multiple semiconductor chips, the bonding wire, and the laminated substrate inside a housing;
filling a first encapsulation layer inside the housing such that the multiple semiconductor chips, the bonding wire, and the laminated substrate will be covered;
filling a second encapsulation layer such that a top of the first encapsulation layer will be covered; and
filling a third encapsulation layer such that a top of the second encapsulation layer will be covered, wherein
the first encapsulation layer is filled inside the housing up to a position higher than an upper surface of the bonding wire, and
hardness of the second encapsulation layer is greater than hardness of the first encapsulation layer, and less than hardness of the third encapsulation layer.

20. The method for manufacturing the semiconductor module according to claim 19, comprising:
first annealing for hardening the first encapsulation layer after the filling the first encapsulation layer and before the filling the second encapsulation layer;
second annealing for hardening the second encapsulation layer after the filling the second encapsulation layer and before the filling the third encapsulation layer; and
third annealing for hardening the third encapsulation layer after the filling the third encapsulation layer.
